(19) United States
(12) Patent Application Publication
(10) Pub. No.: US 2025/0173944 A1
(43) Pub. Date: May 29, 2025

(54) Systems and methods for automatically animating design elements

(71) Applicant: Canva Pty Ltd, Surry Hills (AU)

(72) Inventors: Mathew James Paul MANNING, Thornbury (AU); Elijah SHEPPARD, South Coogee (AU); Ashley Alexander BROCK, Sydney (AU)

(73) Assignee: Canva Pty Ltd, Surry Hills (AU)

(21) Appl. No.: 18/956,189

(22) Filed: Nov. 22, 2024

(30) Foreign Application Priority Data
Nov. 24, 2023 (AU) 2023270351

(51) Int. Cl. G06T 13/80; G06F 30/12

(52) U.S. Cl. CPC G06T 13/80; G06F 30/12

(57) ABSTRACT

Described herein is a computer implemented method for automatically animating a set of design elements. The method includes generating a set of categoriser pre-inputs based on the set of design elements and generating a categoriser input based on the set of categoriser pre-inputs. The categoriser input is processed to determine a category and one or more animations are automatically applied to the set of design elements. Applying the one or more animations to the set of design elements includes determining, based on the category, a first animation for the first design element and applying the first animation to the first design element.

### CROSS-REFERENCE TO RELATED APPLICATION

This application is a U.S. Non-Provisional Application that claims priority to Australian Patent Application No. 2023270351, filed Nov. 24, 2024, which is hereby incorporated by reference in its entirety.

### TECHNICAL FIELD

Aspects of the present disclosure are directed to systems and methods for automatically animating design elements.

### BACKGROUND

Various computer applications for creating and publishing graphic designs exist. Generally speaking, such applications allow users to create a design by, for example, creating a page and adding design elements to that page.

Once a design element has been added to a page, applications typically provide mechanisms by which a user can modify the element—for example by selecting the element (or a part thereof) and changing its colour, size, position, etc.

Background information described in this specification is background information known to the inventors. Reference to this information as background information is not an acknowledgment or suggestion that this background information is prior art or is common general knowledge to a person of ordinary skill in the art.

### SUMMARY

Described herein is a computer implemented method for automatically animating a set of design elements, the method including: generating a set of categoriser pre-inputs based on the set of design elements, wherein generating the set of categoriser pre-inputs includes processing a first design element in the set of design elements to generate a first categoriser pre-input; generating a categoriser input based on the set of categoriser pre-inputs; determining a category by processing the categoriser input; and automatically applying one or more animations to the set of design elements, wherein automatically applying the one or more animations to the set of design elements includes: determining, based on the category, a first animation for the first design element; and applying the first animation to the first design element.

### BRIEF DESCRIPTION OF THE DRAWINGS

In the drawings:

FIG. 1 is a diagram depicting a networked environment in which various features of the present disclosure may be implemented.

FIG. 2 is a block diagram of a computer processing system configurable to perform various features of the present disclosure.

FIG. 3 depicts an example design editor graphical user interface.

FIG. 4 is a flowchart depicting operations implemented within the networked environment of FIG. 1 to animate one or more design elements.

FIG. 5 is a flowchart depicting operations performed by a client system to generate a set of categoriser pre-inputs.

FIG. 6 is a flowchart depicting operations performed by a client system to apply an animation to a design element.

While the description is amenable to various modifications and alternative forms, specific embodiments are shown by way of example in the drawings and are described in detail. It should be understood, however, that the drawings and detailed description are not intended to limit the invention to the particular form disclosed. The intention is to cover all modifications, equivalents, and alternatives falling within the scope of the present invention as defined by the appended claims.

### DETAILED DESCRIPTION

In the following description numerous specific details are set forth in order to provide a thorough understanding of the present invention. It will be apparent, however, that the present invention may be practiced without these specific details. In some instances, well-known structures and devices are shown in block diagram form in order to avoid unnecessary obscuring.

As discussed above, computer applications for use in creating graphic designs are known. Such applications will typically provide mechanisms for a user to create a design having one or more design pages, and modify on each page any elements of a design. One way of modifying a design is to animate one or more of the elements of the design (or one or more design element parts). Another way of modifying a design is to apply transitions into and/or out of (or between) design pages.

In the context of the present disclosure, an animation in respect of a visual design element refers to how such an element is displayed on the page it is part of. Animations may be used, for example, to define how an element will appear (or be initially displayed) on and/or or disappear from (or be finally displayed on) a design page. In other words, a design element may be shown on a design page when that page is initially displayed, or a design element may not be shown on a design page when that page is initially displayed. In the latter case, an animation may define how that element is displayed. An example of such an animation is a “fade in” animation where an element fades into view over a predefined duration. Similarly, an animation may define how an element is removed from display. An example of such an animation is a “fade out” animation where an element fades out of view over a predefined duration. In some embodiments, a design element may have more than one animation, such as a specific animation to appear and another specific animation to disappear (for example, a “fade in” and a “fade out” animation). It will also be appreciated that a single animation type may also encompass both an appearing and disappearing effect (for example, a “fade in/out” animation, which would essentially be the same visual effect as having both a “fade in” and a “fade out” animation). Whilst the examples provided herein are animations in the context of an element appearing and/or disappearing, it will be appreciated that an amination may also more broadly refer to any visual effect on a design element not necessarily causing it to appear to disappear, such as an element moving across a page from one point to the next along a defined path, or an element flashing.

As designs become more complex and have a large number of individual elements, animating can become a complex and time consuming exercise. For example, where a design has many elements manually animating each element of the design may be a time consuming and tedious process. Furthermore, for many users, animating elements in a way that provides an overall design that is cohesive and (ideally) visually appealing may require expertise they do not possess.

To address such issues, the present disclosure provides mechanisms for automatically animating elements of a design.

The techniques disclosed herein are described in the context of a digital design platform that is configured to facilitate various operations concerned with digital designs. In the context of the present disclosure, these operations relevantly include for example, one or more of design creation, design editing, design management/organisation, amongst others.

A digital design platform may take various forms. In the embodiments described herein the digital design platform is a client-server type platform (e.g. one or more client applications and one or more server applications that interoperate to perform the described techniques). The techniques described herein could, however, be performed (or be adapted to be performed) by a stand-alone digital design platform (e.g. an application or set of applications that run on a user's computer processing system and perform the techniques described herein without requiring server-side operations).

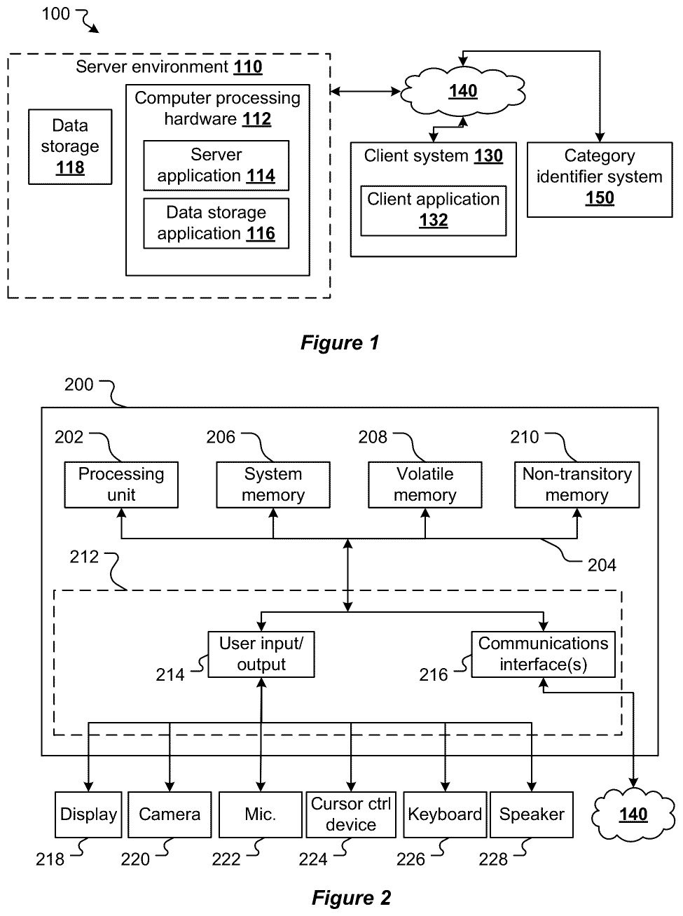

Referring initial to FIG. 1, a networked environment 100 is depicted in which various features of the present disclosure may be implemented.

Networked environment 100 includes a server environment 110 and a client system 130 which communicate via one or more communications networks 140 (e.g. the Internet).

Generally speaking, the server environment 110 includes computer processing hardware 112 (discussed below) on which applications that provide server-side functionality to client applications such as client application 132 (described below) execute. In the present example, server environment 110 includes a server application 114 and a data storage application 116.

In the present embodiment, the server application 114 executes to provide a client application endpoint that is accessible over communications network 140. For example, where server application 114 serves web browser client applications the server application 114 will be a web server which receives and responds (for example) to HTTP requests. Where server application 114 serves native client applications, server application 114 will be an application server configured to receive, process, and respond to specifically defined API calls received from those client applications. The server environment 110 may include one or more web server applications and/or one or more application server applications allowing it to interact with both web and native client applications.

In the present example, server application 114 (and/or other applications of server environment 110) facilitates various functions related to digital designs. These may include, for example, design creation, editing including animating, storage, organisation, searching, storage, retrieval, viewing, sharing, publishing, and/or other functions related to digital designs. The server application 114 (and/or other applications) may also facilitate additional, related functions such as user account creation and management, user group creation and management, user and user group permission management, user authentication, and/or other server side functions.

In the present example, the data storage application 116 executes to receive and process requests to persistently store and retrieve data relevant to the operations performed/services provided by the server environment 110. Such requests may be received from the server application 114, other server environment applications, and/or (in some instances) directly from client applications such as 132. Data relevant to the operations performed/services provided by the server environment 110 may include, for example, user account data, user design data (i.e. data describing designs that have been created by users), template design data (e.g. templates that can be used by users to create designs), design element data (e.g. data in respect of stock elements that users may add to designs), and/or other data relevant to the operation of the server environment 110.

The data storage application 116 may, for example, be a relational database management application or an alternative application for storing and retrieving data from data storage 118. Data storage 118 may be any appropriate data storage device (or set of devices), for example one or more non transient computer readable storage devices such as hard disks, solid state drives, tape drives, or alternative computer readable storage devices.

In server environment 110, server application 114 persistently stores data to data storage device 118 via the data storage application 116. In alternative implementations, however, the server application 114 may be configured to directly interact with data storage devices such as 118 to store and retrieve data (in which case a separate data storage application may not be needed). Furthermore, while a single data storage application 116 is described, server environment 110 may include multiple data storage applications. For example one data storage application 116 may be used for user account data, another for user design data, another for design element data and so forth. In this case, each data storage application may interface with one or more shared data storage devices and/or one or more dedicated data storage devices, and each data storage application may receive/respond to requests from various server-side and/or client-side applications (including, for example server application 114).

As noted, the server environment 110 applications run on (or are executed by) computer processing hardware 112. Computer processing hardware 112 includes one or more computer processing systems. The precise number and nature of those systems will depend on the architecture of the server environment 110.

For example, in one implementation each server environment application may run on its own dedicated computer processing system. In an alternative implementation, two or more server environment applications may run on a common/shared computer processing system. In a further alternative implementation, server environment 110 is a scalable environment in which application instances (and the computer processing hardware 112—i.e. the specific computer processing systems required to run those instances) are commissioned and decommissioned according to demand—e.g. in a public or private cloud-type system. In this case, server environment 110 may simultaneously run multiple instances of each application (on one or multiple computer processing systems) as required by client demand. Where server environment 110 is a scalable system it will include additional applications to those illustrated and described. As one example, the server environment 110 may include a load balancing application which operates to determine demand, direct client traffic to the appropriate server application instance 114 (where multiple server applications 114 have been commissioned), trigger the commissioning of additional server environment applications (and/or computer processing systems to run those applications) if required to meet the current demand, and/or trigger the decommissioning of server environment applications (and computer processing systems) if they are not functioning correctly and/or are not required for current demand.

Communication between the applications and computer processing systems of the server environment 110 may be by any appropriate means, for example direct communication or networked communication over one or more local area networks, wide area networks, and/or public networks (with a secure logical overlay, such as a VPN, if required).

Client system 130 hosts a client application 132 which, when executed by the client system 130, configures the client system 130 to provide client-side functionality/interact with server environment 110 (or, more specifically, the server application 114 and/or other applications provided by the server environment 110). Via client application 132, and as discussed in detail below, a user can make use of the various techniques and features described herein.

The client application 132 may be a general web browser application which accesses the server application 114 via an appropriate uniform resource locator (URL) and communicates with the server application 114 via general world-wide-web protocols (e.g. http, https, ftp). Alternatively, the client application 132 may be a native application programmed to communicate with server application 114 using defined application programming interface (API) calls and responses.

A given client system such as 130 may have more than one client application 132 installed and executing thereon. For example, a client system 130 may have a (or multiple) general web browser application(s) and a native client application.

Networked environment 100 may further include other third party systems, such as a category identifier system 150 (discussed below). Category identifier system 150 communicates with server environment 110 and/or client system 130 via network 140. In this embodiment, category identifier system 150 is located remotely to both server environment 110 and client system 130. However, in other embodiments, category identifier system 150 may be implemented as part of server environment 110. Further, in other embodiments, networked environment 100 may further include a plurality of third party systems.

The present disclosure describes various operations that are performed by applications of the server environment 110 and client application 132. Generally speaking, however, operations described as being performed by a particular application (e.g. server application 114) could be performed by (or in conjunction with) one or more alternative applications, and/or operations described as being performed by multiple separate applications could in some instances be performed by a single application.

The present disclosure describes methods and processing as being performed by client application 132. In certain embodiments, the functionality described may be natively provided by the client application 132 (e.g. the client application 132 itself has instructions and data which, when executed, cause the client application 132 to perform the functionality described herein).

In alternative embodiments, the functionality described herein may be provided by a separate software module (such as an add-on or plug-in) that operates in conjunction with the client application 132 to expand the functionality thereof.

The techniques and operations described herein are performed by one or more computer processing systems.

By way of example, client system 130 may be any computer processing system which is configured (or configurable) by hardware and/or software—e.g. client application 132—to offer client-side functionality. A client system 130 may be a desktop computer, laptop computer, tablet computing device, mobile/smart phone, or other appropriate computer processing system.

Similarly, the applications of server environment 110 are also executed by one or more computer processing systems (the computer processing hardware 112). Server environment computer processing systems will typically be server systems, though again may be any appropriate computer processing systems.

FIG. 2 provides a block diagram of a computer processing system 200 configurable to implement embodiments and/or features described herein. System 200 is a general purpose computer processing system. It will be appreciated that FIG. 2 does not illustrate all functional or physical components of a computer processing system. For example, no power supply or power supply interface has been depicted. However system 200 will either carry a power supply or be configured for connection to a power supply (or both). It will also be appreciated that the particular type of computer processing system will determine the appropriate hardware and architecture, and alternative computer processing systems suitable for implementing features of the present disclosure may have additional, alternative, or fewer components than those depicted.

Computer processing system 200 includes at least one processing unit 202. The processing unit 202 may be a single computer processing device (e.g. a central processing unit, graphics processing unit, or other computational device), or may include a plurality of computer processing devices. In some instances, where a computer processing system 200 is described as performing an operation or function all processing required to perform that operation or function will be performed by processing unit 202. In other instances, processing required to perform that operation or function may also be performed by remote processing devices accessible to and useable (either in a shared or dedicated manner) by system 200.

Through a communications bus 204 the processing unit 202 is in data communication with a one or more machine readable storage (memory) devices which store computer readable instructions and/or data which are executed by the processing unit 202 to control operation of the processing system 200. In this example system 200 includes a system memory 206 (e.g. a BIOS), volatile memory 208 (e.g. random access memory such as one or more DRAM modules), and non-transient memory 210 (e.g. one or more hard disk or solid state drives).

System 200 also includes one or more interfaces, indicated generally by 212, via which system 200 interfaces with various devices and/or networks. Generally speaking, other devices may be integral with system 200, or may be separate. Where a device is separate from system 200, the connection between the device and system 200 may be via wired or wireless hardware and communication protocols, and may be a direct or an indirect (e.g. networked) connection.

Generally speaking, and depending on the particular system in question, devices to which system 200 connects include one or more input devices to allow data to be input into/received by system 200 and one or more output device to allow data to be output by system 200.

By way of example, where system 200 is a personal computing device such as a desktop or laptop device, it may include a display 218 (which may be a touch screen display and as such operate as both an input and output device), a camera device 220, a microphone device 222 (which may be integrated with the camera device), a cursor control device 224 (e.g. a mouse, trackpad, or other cursor control device), a keyboard 226, and a speaker device 228.

As another example, where system 200 is a portable personal computing device such as a smart phone or tablet it may include a touchscreen display 218, a camera device 220, a microphone device 222, and a speaker device 228.

As another example, where system 200 is a server computing device it may be remotely operable from another computing device via a communication network. Such a server may not itself need/require further peripherals such as a display, keyboard, cursor control device etc. (though may nonetheless be connectable to such devices via appropriate ports).

Alternative types of computer processing systems, with additional/alternative input and output devices, are possible.

System 200 also includes one or more communications interfaces 216 for communication with a network, such as network 140 of environment 100 (and/or a local network within the server environment 110). Via the communications interface(s) 216, system 200 can communicate data to and receive data from networked systems and/or devices.

System 200 stores or has access to computer applications (which may also referred to as computer software or computer programs). Generally speaking, such applications include computer readable instructions and data which, when executed by the processing unit 202, configure system 200 to receive, process, and output data. Instructions and data can be stored on non-transient machine readable medium such as 210 accessible to system 200. Instructions and data may be transmitted to/received by system 200 via a data signal in a transmission channel enabled (for example) by a wired or wireless network connection over an interface such as communications interface 216.

Typically, one application accessible to system 200 will be an operating system application. In addition, system 200 will store or have access to applications which, when executed by the processing unit 202, configure system 200 to perform various computer-implemented processing operations described herein. For example, and referring to the networked environment of FIG. 1 above, server environment 110 includes one or more systems which run server application 114 and data storage application 116. Similarly, client system 130 runs a client application 132.

In some cases part or all of a given computer-implemented method will be performed by system 200 itself, while in other cases processing may be performed by other devices in data communication with system 200.

### Graphical User Interface

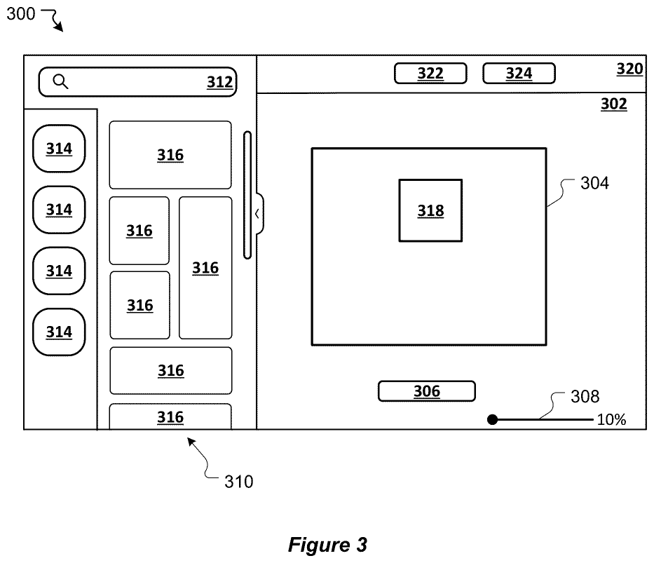

Referring to FIG. 3, in the present disclosure, client application 132 configures client system 130 to provide an editor user interface 300 (UI). Generally speaking, UI 300 will allow a user to create, edit, and output designs. FIG. 3 provides a simplified and partial example of an editor UI. In this example the editor UI 300 is a graphical user interface (GUI).

Editor UI 300 includes a design preview area 302. Design preview area 302 may, for example, be used to display a page 304 (or, in some cases multiple pages) of a design that is being created and/or edited, page 304 including a design element 318. It will be appreciated that a page will often include more than one design element. However, for simplicity, a single design element (in the form of a square box) is illustrated herein.

In this example an add page control 306 is provided (which, if activated by a user, causes a new page to be added to the design being created) and a zoom control 308 (which a user can interact with to zoom into/out of page currently displayed, in this case taking the form of a slider).

Editor UI 300 also includes search area 310. Search area 310 may be used, for example, to search for existing designs and/or other assets that client application 132 makes available to a user to assist in creating and editing designs. Different types of elements may be made available, for example base elements of various types (e.g. text elements, geometric shapes, charts, tables, and/or other types of graphic design elements), media elements of various types (e.g. photographs, vector graphics, shapes, videos, audio clips, and/or other media) that could be associated with another element such as a shape element, design templates, design styles (e.g. defined sets of colours, font types, and/or other assets/asset parameters), and/or other assets that a user may use when creating a design.

In this example, search area 310 includes a search control 312 via which a user can submit search data (e.g. a string of characters). Search area 310 of the present example also includes several type selectors 314 which allow a user to select what they wish to search for—e.g. existing designs they have created or have access to and/or various types of design assets that client application 132 may make available for a user to assist in creating or editing a design (e.g. design templates, design elements, photographs, vector graphics, audio elements, charts, tables text styles, colour schemes, and/or other assets). When a user submits a search (e.g. by selecting a particular type via a type control 314 and entering search text via search control 312) client application 132 may display previews 316 (e.g. thumbnails or the like) of any search results.

Depending on implementation, the previews 316 displayed in search area 310 (and the design assets corresponding to those previews) may be accessed from various locations. For example, the search functionality invoked by search control 312 may cause client application 132 to search for existing designs and/or assets that are stored in locally accessible memory of the system 200 on which client application 132 executes (e.g. non-transient memory such as 210 or other locally accessible memory), assets that are stored at a remote server (and accessed via a server application 114 running thereon), and/or assets stored on other locally or remotely accessible devices.

Editor UI 300 also includes an additional controls area 320 which, in this example, is used to display additional controls. The additional controls may include one or more: permanent controls (e.g. controls such as save, download, print, share, publish, and/or other controls that are frequently used/widely applicable and that client application 132 is configured to permanently display); user configurable controls (which a user can select to add to or remove from area 320); and/or one or more adaptive controls (which client application 132 may change depending, for example, on the type of design element that is currently selected/being interacted with by a user). For example, if a text element is selected, client application 132 may display adaptive controls such as font style, type, size, position/justification, and/or other font related controls may be displayed. Alternatively, if a vector graphic element is selected, client application 132 may display adaptive controls such as fill attributes, line attributes, transparency, and/or other vector graphic related controls may be displayed.

In the present example, editor UI 300 includes an animate elements control 322 and a play (or replay) user interface control 324, both of which will be described further below.

Once a design has been created, client application 132 may provide various options for outputting that design. For example, client application 132 may provide a user with options to output a design by one or more of: saving the design to local memory of system 200 (e.g. non-transient memory 210); saving the design to remotely accessible memory device; uploading the design to a server system; printing the design to a printer (local or networked); communicating the design to another user (e.g. by email, instant message, or other electronic communication channel); publishing the design to a social media platform or other service (e.g. by sending the design to a third party server system with appropriate API commands to publish the design); and/or by other output means.

Alternative interfaces, with alternative layouts and/or alternative tools and functions, are possible. For example, an editor UI such as that partially depicted in FIG. 3 will typically include many other controls that permit pages to be created, edited (by creating/adding page element such as images, text, videos, and/or other elements), and output (e.g. saving to local memory, a server data store such data storage 118, printing, publishing via social media, and/or other means) in various ways.

In order to output a design, client application 132 is be configured to format the design to an appropriate file type. For example, in the present disclosure a design may include an animation of one or more elements. In order to output such a design client application 132 may convert the design from a native format (e.g. a design format used by client application 132 itself) to an alternative format, for example to a video format (such as MPEG4, MOV, AVI, or an alternative video format), an animation format (e.g. an animated GIF format), or an alternative format that is appropriate for animations. The example file formats may be containers around a codec, such codecs including H264, H265 and/or VP1.

Data in respect of designs that have been (or are being) created may be stored in various formats. An example design data format that will be used throughout this disclosure for illustrative purposes will now be described. Alternative design data formats (which make use of the same or alternative design attributes) are, however, possible, and the processing described herein can be adapted for alternative formats.

In the present context, data in respect of a particular design is stored in a design record. Generally speaking, a design record defines certain design-level attributes and includes page data.

Page data of a design defines (or references) one or more page records. Each page record defines a page of the design via one or more page-level attributes and design element data defining elements that have been added to the page.

In the present example, the format of each design record is a device independent format comprising a set of key-value pairs (e.g. a map or dictionary). To assist with understanding, a partial example of a design record format is as follows:

| Attribute | Example |
|---|---|
| Design ID | “designId”: “abc123” |
| Dimensions | “dimensions”: {“width”: 1080, “height”: 1080} |
| Design type | “type”: “presentation” |
| Design name | “name”: “Test Doc 3” |
| Design owner | “owner”: 12ab34cd |
| Edit time | “edited”: “xxx” |
| Page data | “pages”: [{page 1}, . . . {page n}] |

In this example, the design-level attributes include: a design identifier (which uniquely identifies the design); page dimensions (e.g. a default page width and height); a design type (e.g. an indicator of the type of the design, which may be used for searching and/or sorting purposes); a design name (e.g. a string defining a default or user specified name for the design); a design owner (e.g. an identifier of a user or group that owns or created the design); a most recent edit time (e.g. a timestamp indicating when the design was last edited); and page data (discussed below). Additional and/or alternative design-level attributes may be provided, such as attributes regarding creation date, design version, design permissions, and/or other design-level attributes.

In this example, a design record's page data is a set (in this example an array) of page records, each of which defines page data in respect of a page of the design. In this example, a page record's position in a design's page array serves to identify the page and also determines its position in the design (e.g. a page at array index n appears after a page at array index n−1 and before a page at array index n+1). Page order may be alternatively handled, however, for example, by storing page order as an explicit attribute.

To assist with understanding, a partial example of a page record format is as follows:

| Attribute | Example |
|---|---|
| Dimensions | “dimensions”: {“width”: 1080, “height”: 1080} |
| Background | “background”: {“mediaID”: “M12345”} |
| Page duration | “pageDuration”: {“duration”: 15} |
| Transition | “Transition”: {“type”: “ . . . ”, “duration”: 2} |
| Element data | “elements”: [{element 1}, . . . {element n}] |

In this example, the page-level attributes include: dimensions (e.g. a page width and height which, if present, override the default page dimensions defined by the design level dimensions attribute described above); background (data indicating any page background that has been set, for example an asset identifier of an image that has been set as the page background, a value indicating a particular colour of a solid background fill, or data indicating an alternative background); page duration (discussed below); transition (discussed below); and design element data (discussed below). Additional and/or alternative page-level attributes may be provided, such as attributes regarding creation date, design version, design permissions, and/or other page-level attributes.

In this example, the page duration attribute includes data that indicates the length of time that the page will be displayed before transitioning to a next page (if one exists). In the present embodiments, the page duration excludes the time taken for transitions in to or out of the page. Page duration may, however, be defined or determined in various ways. For example, a page duration may be a specifically (e.g. manually) defined duration. Alternatively, a page duration may be automatically determined based on page elements—e.g. the length of time of a video element in the page plays, such that the video commences playing once the page is displayed and continues to be displayed for the duration of the video and upon completion of the video, the next page is immediately displayed. The page duration may be defined in millisecond, seconds, or another suitable time unit.

In this example, a page can be associated with a transition. In the present embodiment, a transition defines how a current page (as a whole) is removed from display and how the next page is initially displayed (e.g. an exit transition). Various transitions are possible, e.g.: having the current page disappear and the next page appear; fading the current page out and then fading the next page in; cross fading between pages; the next page sliding over the current page; and/or alternative transition effects. In this example, the transition attribute includes a type identifier that indicates the transition type and a duration (e.g. in milliseconds or seconds or an alternative unit). In alternative embodiments, separate entry and exit transition attributes may be provided.

In this example, a design page's element data is a set (in this example an array) of element records. Each element record defines an element (or a set of grouped elements) that has been added to the page. In this example, an element record's position in a page's elements array serves to identify the element and also determines the depth or z-index of the element (or element group) on the page (e.g. an element at array index n is positioned above an element at array index n−1 and below an element at array index n+1). Element depth may be alternatively handled, however, for example, by storing depth as an explicit element attribute.

Generally speaking, an element record defines an object that has been added to a page—e.g. by copying and pasting, importing from one or more asset libraries (e.g. libraries of images, animations, videos, etc.), drawing/creating using one or more design tools (e.g. a text tool, a line tool, a rectangle tool, an ellipse tool, a curve tool, a freehand tool, and/or other design tools), or by otherwise being added to a design page.

Different types of design elements may be provided for depending on the system in question. By way of example, base elements and media elements may be provided.

As will be appreciated, different attributes may be relevant to different element types. An element that holds visual media (e.g. an image, video, text, etc.), however, will typically be associated with position and size data

By way of example, an element record for an image type element may include attributes such as the following:

| Attribute | Note | E.g. |
|---|---|---|
| Type | A value defining the type of the element. | “type”: “IMAGE” |
| Position | Data defining the position of the element: e.g. an (x, y) | “position”: (100, 100) |
| | coordinate pair defining (for example) the top left point | |
| | of the element. | |
| Size | Data defining the size of the element: e.g. a (width, | “size”: (500, 400) |
| | height) pair. | |
| Rotation | Data defining any rotation of the element. | “rotation”: 0 |
| Opacity | Data defining any opacity of the element (or element | “opacity”: 1 |
| | group). | |
| Media | Data indicating the media (e.g. an image) that the | “mediaID”: “M12345” |
| identifier | element holds/is used to display | |
| Animation | Data defining any animation that is applied to the | “animation”: { . . . } |
| | element (described further below). | |

A given element record may define additional (and/or alternative) attributes which may, in turn, depend on the type of element in question. For example, a text-type element may include various attributes defining the actual text and text formatting. As another example, a video-type element may include attributes defining start and/or end trim points.

In present embodiments, design elements can be associated with one or more animations.

In this example, if a design element is associated with an animation, data in respect of that animation is stored in an animation attribute of the element's element record. However, in other embodiments, an animation may be stored elsewhere such as in an animation attribute of the design record or a page record. In such cases, the animations are applied at a design or page level, thus applying to all relevant elements (such as all elements having certain predetermined attributes such as a predetermined element type, etc.) in that design or page.

In the present embodiments, an element's animation data may be used to define an entry animation data (defining how an element appears, for example a “fade in” animation) and/or exit animation data (defining how an element disappears, for example a “fade out” animation).

In the present example, animation data for a given animation may include an animation identifier that uniquely identifies a particular type of animation. The animation identifier may, for example, be an enum, a keyword (such as “fade”, “blur”, or “rise”), or any other value that identifies a type of animation.

Animation data for a given animation may also include one or more animation parameters. The types of parameters available may depend on the type of animation. For example various animation types may be associated with an animation duration parameter indicating a length of time that the animation occurs over. Other animation parameters may, depending on the type of animation, define an animation direction (indicating a general direction of movement), an animation path (indicating a movement path), an animation intensity (controlling the scale or distance applied to an animation), an entry parameter (which indicates whether the animation is to be applied to entry of the element), an exit parameter (which indicates whether the animation is to be applied to exit of the element), and/or other animation parameters.

By way of more specific examples, animations such as the following types may be made available: a “fade” animation—where the element is faded in and/or out over a duration (which may be a default or user defined animation parameter); a “rise” animation—where the element enters and/or exits by translating vertically over a distance and/or for a duration (where distance and/or duration may be default or user defined animation parameters); a “pan” animation—where the element enters and/or exits while translating horizontally over a distance and/or for a duration (where distance and/or duration may be default or user defined animation parameters); a “blur” animation—where the element is faded in from a defined blur radius to a blur radius of 0 over a defined duration (where the defined blur radius and/or duration may be default or user defined animation parameters); a “drift” animation—where an element is slowly translated horizontally across a large distance (where duration and/or distance may be default or user defined animation parameters).

As indicated above, animation parameters may be dependent on the type of animation. For example, a “blur” animation type above includes the starting blur radius parameter. Some animations (including the examples provided above) may also include non-visual parameters such as an audio parameter that indicates an audio clip or effect (or any sound) that plays for a given animation.

In many applications, animating a design element generally involves selecting the element in question, selecting an animation type to apply to the element, and then selecting animation parameters for the animation (or accepting default animation parameters). Additional and/or alternative types of animations may be provided. Further, different data attributes may be used to describe animations.

In most cases, as a default, an element will not be animated. In this case (and in the context of the element record format described above), the animation attributes will not be populated (or may be populated with a value indicating that no animation is applied).

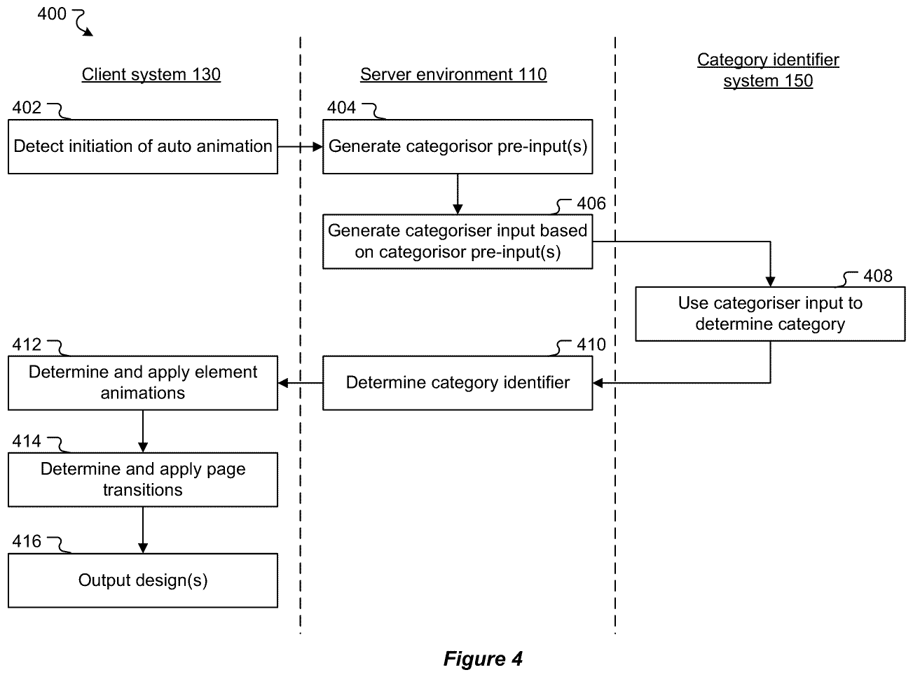

Referring to FIG. 4, a method 400 for automatically animating a set of design elements will be described.

The operations of method 400 will be described as being performed by client system 130, server environment 110 or category identifying system 150. In alternative embodiments, however, the processing described may be performed by one or more alternative applications running on client system 130, server environment 110 and/or other computer processing systems. In this example, the server-side processing is described as being coordinated by server application 114 (which may cause other server-side applications to perform various operations). In alternative embodiments, however, the operations of method 400 could be coordinated and/or performed by alternative applications, or could be performed by a single stand-alone application.

In the present example, method 400 is triggered at client application 132. In particular, client application 132 detects initiation of an automatic animation process at 402. This may, for example, be detecting user activation of a UI control (such as the animate elements control 322). In alternative embodiments, the automatic animation process may be triggered by other events (either user-initiated or automatic).

On detecting initiation of an automatic animation process at 402, client application 132 generates an automatic animation request and communicates this to the server application 114. The automatic animation requests includes data that allows a set of input elements (i.e. the design elements that are to be animated) to be identified.

The set of input elements for method 400 may be determined in various ways. As one example, the set of input elements may be one or more individual elements from a design page (or a set of design pages). For example, a user may select (via a user interface such as UI 300 above) one more design elements (such as element 318) and then initiate automatic animation of the selected element(s) by activating a UI control such as the animate elements control 322.

As another example, the set of input elements may be all elements on one or more pages of a design. For example, while a design (or a particular page of a design) is displayed in a user interface (such as UI 300 above) a user may activate a UI control (such as the animate elements control 322). In response, the user may be displayed with an option of animating the elements on a currently displayed page, selecting specific pages of a design, or selecting all pages of a design.

As a further example, activation of a UI control (such as the animate elements control 322) may provide a user with additional options for selecting elements to be animated. For example, an element selection UI may be displayed that allows a user to select elements based on particular criteria. E.g., an element selection UI may provide controls for a user to select one or more elements based on element type, element page, and/or other criteria.

At 404, server application 114 receives the automatic animation request and generates a set of one or more categoriser pre-inputs. If required, the server application 114 may save the design that the set or input elements are part of to data storage such as 118 (via data storage application 116). Server application 114 generates the set of categoriser pre-inputs based on the set of input elements. In the present embodiment, each categoriser pre-input is a text string (e.g. a word or a phrase).

In the present embodiment, server application 114 generates the set of categoriser pre-inputs based on element data (e.g. data from the element records of the input elements) and, in certain cases, page data (e.g. data from the page record(s) defining the page(s) that the input elements belong to). In other embodiments, page data need not be considered when generating the set of categoriser pre-inputs, and/or server application 114 may generate the set of categoriser pre-inputs based on other data (e.g. design-level data from the design that the input elements belong to).

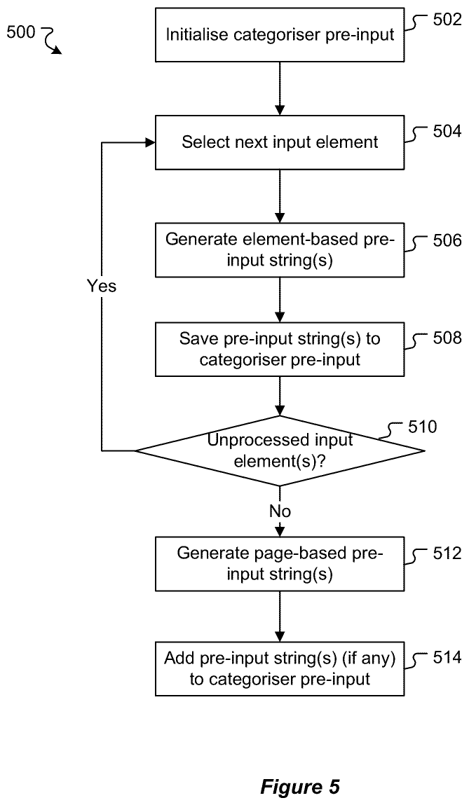

Turning to FIG. 5, an example method 500 for generating the set of categoriser pre-inputs will be described.

At 502, server application 114 initialises the set of categoriser pre-inputs that will in due course be returned. In the present example the set of categoriser pre-inputs is a string (and initialisation involves generating an empty string).

At 504, server application 114 selects an unprocessed input element from the set of input elements. Input elements may be processed in any order. For example, and in the context of design records as discussed above, if the set of input elements is all elements of a particular page server application may select elements in the order they appear in the page's elements array. As another example, if the set of input elements is all elements of a particular (multi-page) design, server application 114 may iterate over the design's page records (e.g. in the order they appear the design's pages array) and for each page record select elements in the order they appear in that page's elements array.

At 506, server application 114 processes the selected input element (e.g. the selected element's element record) to generate zero or more pre-input strings. Pre-input strings that are generated based on an element may be referred to as element-based pre-input strings. Generally speaking, server application 114 generates pre-input strings based on an element by either extracting text from the element data or by processing data associated with the element to generate text.

The particular manner in which an element is processed to generate pre-input strings may depend on the type of element and the type of media the element holds. By way of example, processing a selected input element to generate element-based pre-input strings may include one or more of the following:
Generating one or more text content based pre-input strings which are based on text content of an element—that is, text that is actually displayed by a text (or other) type element. Generating a text content based pre-input string may include extracting the entirety of the text displayed by an element and including this in either a single pre-input string or splitting such text into multiple pre-input strings. Alternatively, generating a text content based pre-input string may involve processing actual text displayed by an element to generate a summary thereof, and generating one or more pre-input strings based on that text summary. Processing the text of a text element to generate a summary may be performed in any appropriate way, for example by an appropriate machine learning model or an alternative natural language (or other) processing technique.
Generating one or more text format based pre-input strings which are based on the format of the text content of an element. Text format based pre-input strings may, for example, include strings that define (or are based on) properties such as: font type (and/or font family); font size; text hierarchy level; font style (e.g. bold, italic, underline, strikethrough etc.); and/or other text properties.
Generating one or more media content based pre-input strings that are based on and describe non-text media content of an element. Generating a media content based pre-input string may include processing the media of an element to generate a semantic (or other) text description thereof, and generating one or more pre-input strings based on that text description. Processing the non-text media of an element to generate a text description may be performed in any appropriate way, for example by a machine learning model or an alternative processing technique. For example, an image media item may be processed to generate a text description by a machine learning model such as BLIP-2, an alternative machine learning model, or an alternative processing technique. Video, audio, and/or other non-text media items may be also be processed to generate text descriptions thereof using appropriate machine learning models or other processing techniques.
Generating one or more metadata based pre-input strings based on metadata associated with either a selected element or the media of a selected element (noting that an element's media may be associated with its own metadata). For example, metadata may be taken from a “keywords” attribute of an element or an element's media. Keywords may be used to describe various attributes or properties of an element or its media, for example a shape of an element (such as “square”, “rectangle”, etc.), a style of an element (such as “business”, “social”, etc.), and/or any other attributes or properties of an element. As another example, metadata may be taken from a “title” attribute of an element or element's media which provides a text description (e.g. a string) of the media. A media's title attribute may be provided by a user who imports the media into the system, or may be automatically generated (e.g. by processing the media to generate a description thereof as described above).
Generating one or more colour based pre-input strings based on colours of an element or the element's media. For example, for vector graphic type elements server application 114 may generate pre-input string(s) based on colours defined by the vector graphic (e.g. by the stroke, fill, and or other vector graphic attributes that define one or more colours). Alternatively, or in addition, element or media metadata may include one or more metadata attributes that define one or more colours or colour schemes (e.g. dominant colours of the element or media, or a colour scheme of the element or media). In this case, server application 114 may generate pre-input string(s) based on such metadata. By way of further example, the media of an element (or the media of all elements in the set of input elements) may be processed to identify one or more dominant colours defined by that/those elements, and server application 114 may generate pre-input string(s) based on the dominant colours that are identified.

Server application 114 may be configured to generate additional or alternative element-based pre-input strings based on the types of elements, the types of media, the available element data, and/or the available media data.

At 508, server application 114 adds any pre-input strings generated at 506 to the categoriser pre-input. In the present example, server application 114 does so by appending each pre-input string generated at 506 to the categoriser pre-input initialised at 502. As one example, the categoriser pre-input may take the form of a plurality of arrays, each array storing pre-input strings of a particular type. For example, the categoriser pre-input may include: a “colours” array for storing pre-input strings that are in respect of/describe colours; a “media” array for storing pre-input strings that provide media descriptions (which, as noted above, may be based on media metadata such as titles and/or generated descriptions); and/or other arrays. Each pre-input string generated at 506 will be added to the relevant array.

In other embodiments, the categoriser pre-input may be a single string. In this case, when appending a particular pre-input string to the categoriser pre-input server application 114 may add a separator such as a comma to the categoriser pre-input to allow separation of individual pre-input strings.

At 510, server application 114 determines whether there are any unprocessed elements from the set of input elements. If so, processing proceeds to 504. If not, processing proceeds to 512.

At 512, server application 114 processes page data in respect of the page that the set of input elements belong to (e.g. the page record of the relevant page) to generate zero or more pre-input strings. These may be referred to as page-based pre-input strings. Generally speaking, server application 114 may generate a page-based pre-input string by extracting text from the page data or by further processing page data to generate a text string.

By way of example, processing page data in respect of a page to generate zero or more page-based pre-input strings may include processing page duration data to generate a pre-input string. For example, where a page is associated with a page duration (e.g. via a duration attribute as described above or other data) server application 114 may generate a text string that describes the duration based on the duration data (which will typically be numeric—e.g. a number of milliseconds of the like). By way of specific example, for a page with a duration of less than 2 seconds server application 114 may generate a pre-input string such as “fast” and for a page with a duration of more than 8 seconds server application 114 may generate a pre-input string such as “slow”. Alternative threshold durations and associated text strings may be used. In another example, client application may use an actual page duration value (e.g. a number of milliseconds) as the page input string (converting the numeric value—e.g. 3000—to a corresponding text value—e.g. “3000”).

Server application 114 may be configured to generate additional or alternative page-based pre-input strings based on the available page data.

At 514, server application 114 adds any page-based pre-input page strings generated at 512 to the categoriser pre-input. In the present example, server application 114 does so by appending each pre-input string generated at 510 to the categoriser pre-input initialised at 502 (and populated with element-based pre-input strings at 508).

As noted, in certain embodiments server application 114 need not consider page data when generating categoriser pre-inputs. In this case 512 and 514 need not be performed. Furthermore, where page data is considered, it may be processed before (or in parallel with) the processing of element data rather than after as illustrated.

In certain embodiments, server application 114 is configured to apply a maximum word or character length to the set of categoriser pre-inputs. By way of example, server application 114 may limit the set of categoriser pre-inputs to a maximum of 200 words or 1000 characters. When this limit is reached, server application 114 will not generate any further element- or page-based pre-input strings.

Looking at an example (referred to herein as Example 1), the categoriser pre-input for a set of input design elements may include pre-input strings such as:
The text content based pre-input string “invite you to their wedding” (based, for example, on actual text of an element);
The text content based pre-input string “request the pleasure of your company” (based, for example, on actual text of an element);
The keyword based pre-input string “special day” (based, for example, on actual text of an element);
The media content based pre-input string “cake” (based, for example, on a keyword associated with an element holding a picture of a cake);
The media content based pre-input string “flower” (based, for example, on processing an image media item to generate a text description of it);
The media content based pre-input string “rose”;
The media content based pre-input string “gold leaf”.

In other embodiments, method 500 (and step 404) maybe performed by client application 132 with the categoriser pre-inputs sent to server application 114 for further processing.

Returning to FIG. 4, once the categoriser pre-input(s) have been generated server application 114 uses the categoriser pre-inputs to generate a categoriser input (at 406). This involves processing the categoriser pre-inputs to generate an appropriate categoriser input for the category identifier system 150 that is being used.

The specific processing performed to generate the categoriser input, and the format of that input, will depend on the specific category identifier system 150 that is used. In the present example, category identifier system 150 is a machine learning model that is trained to process an input (e.g. a prompt such as a text string) and return an output (e.g. a category description).

By way of more specific example, in one embodiment the category identifier system 150 may be (or make use of) a large language model (LLM). By way of example, the LLM may be an OpenAI LLM, or an alternative LLM. In this embodiment, the categoriser input includes a prompt that is based on the set of categoriser pre-inputs and other prompt generation data. The prompt is generated so that the LLM will generate output in a desired form (e.g. a category name or data from which a category name can be extracted or generated).

A LLM prompt may be made up of one or more prompt components. Various prompt components may be used, and as will be appreciated by those skilled in the art the specific wording of each prompt component may be varied in order to improve or change the output provided by the LLM. By way of illustration only, a LLM prompt may be made up of components such as
A context setting component that provides context to the LLM. This component may be a string such as “This is a design categorisation task”.
An output setting component that indicates to the LLM the output required. This component may be a string such as “Return a category name”.
An available categories component which indicates the categories that can be output by the LLM. This component may be a string such as “Available categories are comical, solemn, minimalist, retro, vintage, . . . ”. Additional/alternative categories may be defined and further text may be included to describe the characteristics of each category. For example text such as “solemn designs are often in subdued colours, . . . ” may be added to assist a LLM in identifying “solemn” category designs.
A design description component which describes the design that is to be categorised to the LLM. The design description component includes or is based on the categoriser input generated at 406.

Once server application 114 has generated the categoriser input it generates a categorisation request that includes the input and communicates the request to category identifier system 150.

At 408, category identifier system 150 receives the categorisation request from the server application 114. The categorisation request includes the categoriser input generated at 406. On receiving the categorisation request, category identifier system 150 processes the categoriser input to generate a categoriser output. The categoriser output includes data that identifies a category or data that can be processed to identify a category. Category identifier system 150 then generates a categorisation response and communicates it to server application 114. The categorisation response includes the categoriser output.

As described above, in the present example category identifier system 150 is (or makes use of) a trained machine learning model, such as a large language model (LLM). In the LLM example described above, the categoriser output will be a single text word that defines the category such as: “Elegant” or “Bold”. In alternate embodiments, the categoriser output may take other usable forms, such as a multiple words of text or an identifier that can be used to identify a category.

At 410, server application 114 receives the categorisation response from the category identifier system 150. On receipt, and if required, the server application 114 processes the response to determine a category identifier. As one example, this may involve converting the categorisation response into a category identifier or enum. For example, if the categoriser response is “Elegant”, server application 114 may convert the response to an identifier corresponding to the category “Elegant” (which could be a numerical value or some other identifier). In other embodiments, the categorisation response may be useable in its original form and processing to generate a category identifier may not be necessary. Server application 114 then communicates the category identifier to the client application 132.

At 412, client application 132 receives the category identifier from server application 114. Based on the identified category, client application 132 automatically determines and applies element animations to the set of input elements.

In the present embodiment, client application 132 automatically determines and applies element animations to the set of input elements based on the identified category and a set of predefined element animation rules.

Element animation rules may be defined and recorded in various ways. In the present embodiment, and generally speaking, each element animation rule is associated with rule criteria data and animation data. An element animation rule's criteria data define one or more criteria that are used to determine whether the rule applies to a given element. A rule's animation data defines an animation that is to be applied to a design element that satisfies the rule's criteria.

For a given element animation rule, the rule criteria may include a category criterion. The category criterion will specify a particular category (corresponding to one of the categories that is identified and returned by the category identifier system 150) to which the given element animation rule applies.

For a given element animation rule, the rule criteria will also define a set of one or more design element criteria. The set of design element criteria will identify whether the rule applies to a particular element or not. Each design element criterion may correspond to or be otherwise based on one or more element attributes. For example, design element criteria may include criteria such as:
Content type criteria, which may be based on a design element's type attribute which will generally indicate whether the content of the design element is text, an image, a video etc.
Element size criteria which may be based on an element's size attribute. For example, a rule may apply to small elements or to large elements. Correspondingly, if an element is within a predefined size range (e.g. 100×100 pixels or less), it will be determined to be a “small” element, whereas if an element is within another predefined size range (where the lower end of this range is greater than the upper end of the “small” size range—e.g. 400×400 pixels or more) the element may be determined to be a “large” element. Additional element sizes may be defined—for example a “medium” size (with a corresponding size range that fits between the small and large element size ranges). Further, sizes may also be relative to the size of the design page, for example, an area 10% or less than the size of the entire design page may be “small”.
Text size criteria (applicable to design elements that define text). Text size criteria may, for example, be based on font size—e.g. heading text (font size>=x), sub heading text (font size<x and font size>=y), body text (font size<y and character length>n, e.g. n=40). Alternatively, or in addition, text size criteria may be based on text hierarchy levels—e.g. heading text (hierarchy levels 1 and 2), sub heading text (hierarchy levels 3 or 4), body text (hierarchy levels 5 or 6). Text size criteria may be alternatively defined.

For a given element animation rule, the animation data will define a particular type of animation that is to be applied (for example rise, fade, drift, etc.) to an element that satisfies that rule's criteria. Animation data may also define one or more animation parameters relevant to the animation that is to be applied. Examples of animation parameters may include an animation timing/duration, animation speed, animation direction, animation distance, animation path, and/or other data.

By way of example, a partial set of element animation rules associated with the example “elegant” and “professional” categories noted above may be as follows:

| Category criteria | Element criteria | Animation data |
|---|---|---|
| Elegant | fontSize: heading | animation Type: fade |
| | | animationDuration: long |
| Elegant | elementSize: small | animationType: rise |
| | | animationDuration: medium |
| Elegant | elementSize: large | animationType: pan |
| | | animationDuration: long |
| Professional | fontSize: heading | animation Type: fade |
| | | animationDuration: long |
| Professional | elementSize: small | animationType: drift |
| | | animationDuration: short |
| Professional | elementSize: small | animation Type: rise |
| | | animationDuration: medium |
| Professional | elementType: logo | animationType: none |

In this particular example, the criteria include determining whether an element's font size is a “heading” size or not. As noted above, whether an element satisfies this criteria may be based on the font size and/or text hierarchy level of the element's text.

In this particular example, the element criteria include determining whether an element's size is large or small. As noted above, this determination may be made based on the element's size data.

In this particular example, the element criteria include determining whether an element is a “logo” or not. Client application 132 may be configured to determine whether an element is a logo in various ways. As one example, an element may be associated with metadata (e.g. an element type or other metadata) that directly indicates whether the element is a logo or not. Alternatively, client application 132 may determine whether an element is a logo based on one or more of the element's size, shape, position, media, and/or other element attributes. For example, client application 132 may be configured to determine that an element is a logo if: it is less than a defined size (e.g. 100×100) AND it has a rectangular shape AND it is positioned at the bottom left or bottom right of the page AND it's media is a vector graphic.

Alternative element animation rules based on alternative categories and/or element criteria may be implemented.

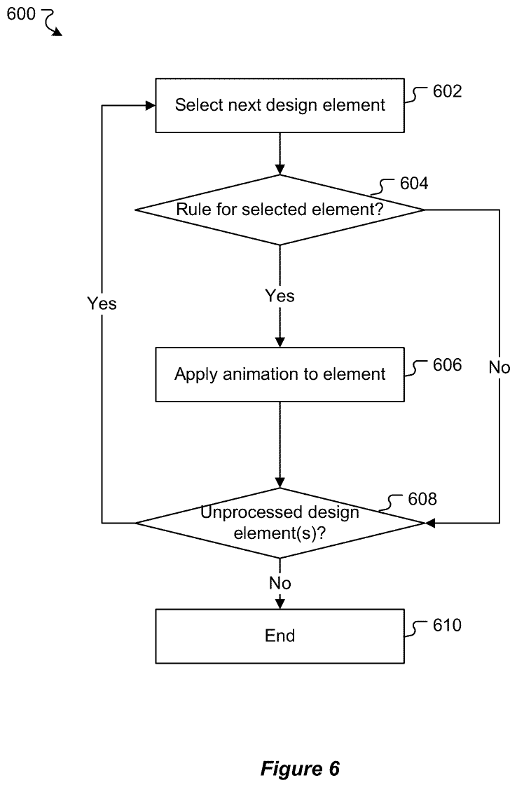

Referring to FIG. 6, a method 600 for applying an animation to an element will be described. That is, method 600 provides a more detailed breakdown of step 410.

At 602, client application 132 selects a specific element from the set of design elements. The selected element will have associated element data (e.g. a set of attributes defined by its element record).

At 604, client application 132 determines whether an animation rule applies to the selected element. This determination is made based on the rule criteria, the selected element's attributes, and the category determined for the set of input elements. If there is an applicable rule, the method proceeds to 606. If there is no applicable rule, the method proceeds to 608.

At 606, client application 132 applies the animation (if any) defined by the applicable animation rule to the selected element. Client application 132 applies the animation based on the animation data associated with the applicable rule (which, as described above, will define a particular type of animation and may also define other animation parameters). With the example design data format described above, client application 132 applies an animation to a selected design element by writing relevant data to the element's “animation” attribute.

At 608, client application 132 determines if any elements in the set of design elements have not been processed (that is, have been through method 600). If so, 602 to 606 are repeated, which continues until all elements of the set of design elements have been processed.

At 610, once all elements in the set of design elements have been processed, method 600 ends.

In certain embodiments, client application 132 may also be configured to automatically determine and apply one or more page transitions. Referring back to FIG. 4, this is indicated at 414. Determining and applying page transitions could, however, be performed before (or in parallel) with determining and applying element animations.

In other embodiments, determining and applying page transitions may be performed instead of determining and applying element animations, or need not be performed. Determining and applying page transitions may be appropriate, for example, where the set of input elements belong to one or more design pages. In this case, each input page that the set of input elements belong to may be processed separately.

In the present example, client application 132 automatically determines and applies page transitions based on the identified category and a set of predefined page transition rules.

Page transition rules may be defined and recorded in various ways. In the present embodiment, and generally speaking, each page transition rule is associated with rule criteria data and transition data. A page transition rule's criteria data define one or more criteria that are used to determine whether the rule applies to a given page. A page transition rule's transition data defines a transition that is to be applied to a page that satisfies the rule's criteria.

For a given page transition rule, the rule criteria may include a category criterion. The category criterion will specify a particular category (corresponding to one of the categories that is identified and returned by the category identifier system 150) to which the given page transition rule applies.

For a given page transition rule, the rule criteria will also define a set of one or more design page criteria. The set of design page criteria will identify whether the rule applies to a particular page or not. Each design page criterion may correspond to or be otherwise based on one or more page attributes. For example, design page criteria may include criteria such as whether a page duration is greater than a predefined minimum duration (which could be 1.5 seconds, for example). If the page duration is less than the predefined minimum duration, the page transition will not apply.

For a given page transition rule, the transition data will define a particular type of page transition that is available (for example “fade in” transition). Transition data may also define data associated with a transition, for example a transition timing/duration, transition speed, transition distance, and/or other data.

By way of example, some example transitions may be as follows:

| Page transition | Transition data |
|---|---|
| Slide | transitionType: slide |
| | transitionDirecton: up |
| | transitionDuration: long |
| Wipe | transitionType: wipe |
| | transitionColour: red |
| | transitionDuration: long |

In present embodiments, 412 (along with method 600) and 414 are performed on a page by page basis. However, in other embodiments, 412 (along with method 600) and 414 may be performed substantially simultaneously on the entire design.

At 416, client application 132 outputs the set of design elements (which have now had any applicable animations applied) to be previewed to the user. In the present embodiment, client application 132 may display the set of design elements within preview area 302 by redisplaying the page (or pages) to which the elements in the set of input elements belong. In illustrated examples, play (or replay) user interface control 324 allows a user to view the animated elements, and if multiple pages are involved page navigation controls (e.g. next and/or previous page controls) may also be provided.

In the present embodiment, if the set of input elements includes elements from multiple design pages, 402 to 406 are performed for all pages of a design to be inputted into category identifier system 150. 410 and 412 are, however, performed on a page by page basis.

In other embodiments, if the set of input elements includes elements from multiple design pages, the elements of each design page are processed separately according to method 400. For example, if the set of input elements includes elements from a first design page and as second design page, a first instance of method 400 is performed on the elements from the first design page and a second instance of method 400 is performed on the elements from the second design page. In alternative embodiments, however, method 400 may be performed (or be adapted to be performed) on the set of input elements as a whole.

Client application 132 may provide user controls which, based on the previewed animated design elements, allow a user to confirm that the changes (that is, the animations) to the design should be accepted or, alternatively, to reject the changes. In the examples herein, the options to confirm or to reject to the changes may be presented to the user by way of respective user interface controls within additional controls area 320, or another area such as towards a corner of design preview area 302, or as a pop-up of these options. If the user confirms acceptance of the changes, the animations are incorporated into the design (thus, saved in the design record). If the user chooses to reject the changes, the design will revert back to its state prior to the animations being applied.

Further, in other embodiments, some elements may be associated with an attribute that prevents automated amination. In this case, such elements are ignored in processing and will not be automatically animated.

The storage location for design data (e.g. design records) will depend on implementation.

For example, in the networked environment described above design records are (ultimately) stored in/retrieved from the server environment's data storage 118. This involves the client application 132 communicating design data to the server environment 110—for example to the data storage application 116 (which may be via server application 114) which stores the data in data storage 118. Alternatively, or in addition, design data may be locally stored on a client system 130 (e.g. in non-transient memory 210 thereof).

In the example described above, category identifier system 150 utilises a trained machine learning model (and in particular a LLM) to determine a category. System 150 (or an alternative system) may, however, be configured to determine a category based on an input string (or a set of input words) in alternative ways. For example, rather than using a LLM an alternative machine learning model may be specifically trained to categorise input prompts into a desired set of categories. Such a model may be trained based on a set of training data that includes example input prompts and corresponding categories. In other embodiments, system 150 (or an alternative system) may determine animation categories by other (non-machine learning) natural language processing techniques.

In other embodiments, alternate approaches may be taken. One example is a word search based approach. In such an approach, the words in a design are used to search for predefined sets of words, where each predefined set of words relates to a certain category. For example the word “business” (if used in text or images in the design) may be part of a set relating to the category “Professional”, whereas the words “wedding” or “anniversary” may be part of a set relating to the category “Elegant”. Based on the count of words found for each particular set, the set with the highest word count would be selected and the category associated with that set output.

Where client application 132 operates to display controls, interfaces, or other objects, client application 132 does so via one or more displays that are connected to (or integral with) system 200—e.g. display 218. Where client application 132 operates to receive or detect user input, such input is provided via one or more input devices that are connected to (or integral with) system 200—e.g. a touch screen, a touch screen display 218, a cursor control device 224, a keyboard 226, and/or an alternative input device.

In the above embodiments certain operations are described as being performed by the client system 130 (e.g. under control of the client application 132) and other operations are described as being performed at the server environment 110. Variations are, however, possible. For example in certain cases an operation described as being performed by client system 130 may be performed at the server environment 110 and, similarly, an operation described as being performed at the server environment 110 may be performed by the client system 130. Generally speaking, however, where user input is required such user input is initially received at client system 130 (by an input device thereof). Data representing that user input may be processed by one or more applications running on client system 130 or may be communicated to server environment 110 for one or more applications running on the server hardware 112 to process. Similarly, data or information that is to be output by a client system 130 (e.g. via display, speaker, or other output device) will ultimately involve that system 130. The data/information that is output may, however, be generated (or based on data generated) by client application 132 and/or the server environment 110 (and communicated to the client system 130 to be output).

Furthermore, in certain implementations a computer processing system 300 may be configured (by an application running thereon) to perform the processing described herein entirely independently of a server environment 110. In this case, the application running on that system is a stand-alone application and all instructions and data required to perform the operations described above are stored on that system.

The flowcharts illustrated in the figures and described above define operations in particular orders to explain various features. In some cases the operations described and illustrated may be able to be performed in a different order to that shown/described, one or more operations may be combined into a single operation, a single operation may be divided into multiple separate operations, and/or the function(s) achieved by one or more of the described/illustrated operations may be achieved by one or more alternative operations. Still further, the functionality/processing of a given flowchart operation could potentially be performed by (or in conjunction with) different applications running on the same or different computer processing systems.

The present disclosure provides various user interface examples. It will be appreciated that alternative user interfaces are possible. Such alternative user interfaces may provide the same or similar user interface features to those described and/or illustrated in different ways, provide additional user interface features to those described and/or illustrated, or omit certain user interface features that have been described and/or illustrated.

In the above description, certain operations and features are explicitly described as being optional. This should not be interpreted as indicating that if an operation or feature is not explicitly described as being optional it should be considered essential. Even if an operation or feature is not explicitly described as being optional it may still be optional.

Unless otherwise stated, the terms “include” and “comprise” (and variations thereof such as “including”, “includes”, “comprising”, “comprises”, “comprised” and the like) are used inclusively and do not exclude further features, components, integers, steps, or elements.

It will be understood that the embodiments disclosed and defined in this specification extend to alternative combinations of two or more of the individual features mentioned in or evident from the text or drawings. All of these different combinations constitute alternative embodiments of the present disclosure.

The present specification describes various embodiments with reference to numerous specific details that may vary from implementation to implementation. No limitation, element, property, feature, advantage or attribute that is not expressly recited in a claim should be considered as a required or essential feature. Accordingly, the specification and drawings are to be regarded in an illustrative rather than a restrictive sense.

1. A computer implemented method for automatically animating a set of design elements, the method including:
generating a set of categoriser pre-inputs based on the set of design elements, wherein generating the set of categoriser pre-inputs includes processing a first design element in the set of design elements to generate a first categoriser pre-input;
generating a categoriser input based on the set of categoriser pre-inputs;
determining a category by processing the categoriser input; and
automatically applying one or more animations to the set of design elements, wherein automatically applying the one or more animations to the set of design elements includes:
determining, based on the category, a first animation for the first design element; and
applying the first animation to the first design element.

2. The computer implemented method according to claim 1, wherein generating the set of categoriser pre-inputs includes processing a plurality of design elements in the set of design elements to generate a plurality of categoriser pre-inputs.

3. The computer implemented method according to claim 1, wherein processing the first design element to generate the first categoriser pre-input includes generating a text content based pre-input that is based on text content of the first design element.

4. The computer implemented method according to claim 1, wherein processing the first design element to generate the first categoriser pre-input includes generating a text format based pre-input that is based on a format of text content of the first design element.

5. The computer implemented method according to claim 1, wherein processing the first design element to generate the first categoriser pre-input includes generating a metadata based pre-input that is based on metadata associated with the first design element.

6. The computer implemented method according to claim 1, wherein:
generating the set of categoriser pre-inputs includes processing a second design element in the set of design elements to generate a second categoriser pre-input; and
processing the second design element to generate the second categoriser pre-input includes generating a media content based pre-input that is based on media content of the second design element.

7. The computer implemented method according to claim 6, wherein the media content based pre-input includes text describing the media content of the second design element.

8. The computer implemented method according to claim 1, wherein:
the first design element is associated with a design page; and
generating the set of categoriser pre-inputs includes generating a page-based pre-input string, the page-based pre-input string being based on page data associated with the design page.

9. The computer implemented method according to claim 1, wherein determining the category by processing the categoriser input includes inputting the categoriser input into a category identifier system and receiving the determined category as an output of the category identifier system.

10. The computer implemented method according to claim 9, wherein the category identifier system includes a machine learning model.

11. The computer implemented method according to claim 9, wherein the machine learning model is a large language model, and wherein generating the categoriser input includes generating a prompt for the large language model.

12. The computer implemented method according to claim 1, wherein the set of design elements include all elements of a current design.

13. The computer implemented method according to claim 1, wherein the set of design elements includes a plurality of design elements and applying one or more animations to the set of design elements further includes:
determining, based on the category, a respective animation for each of the plurality of design elements; and
applying the respective animation to each of the plurality of design elements.

14. The computer implemented method according to claim 1, wherein the first animation for the first design element is determined based on a set of predefined element animation rules.

15. The computer implemented method according to claim 14, wherein each predefined element animation rule is associated with:
rule criteria data which is used to determine whether an animation rule applies to an element; and
animation data which is used to determine a particular animation that is to be applied to an element that the animation rule applies to.

16. The computer implemented method according to claim 15, wherein the rule criteria data for a first animation rule in the set of predefined animation rules includes one or more of: a content type criterion; an element size criterion; a text size criterion; a text hierarchy level criterion.

17. A system including:
one or more computer processing units; and
one or more non-transitory computer-readable media storing instructions which, when executed by the one or more computer processing units, cause the one or more computer processing units to perform a method for automatically animating a set of design elements, the method including:
generating a set of categoriser pre-inputs based on the set of design elements, wherein generating the set of categoriser pre-inputs includes processing a first design element in the set of design elements to generate a first categoriser pre-input;
generating a categoriser input based on the set of categoriser pre-inputs;
determining a category by processing the categoriser input; and
automatically applying one or more animations to the set of design elements, wherein automatically applying the one or more animations to the set of design elements includes:
determining, based on the category, a first animation for the first design element; and
applying the first animation to the first design element.

18. One or more non-transitory computer-readable media storage storing instructions executable by one or more computer processing units to cause the one or more computer processing units to perform a method for automatically animating a set of design elements, the method including:
generating a set of categoriser pre-inputs based on the set of design elements, wherein generating the set of categoriser pre-inputs includes processing a first design element in the set of design elements to generate a first categoriser pre-input;
generating a categoriser input based on the set of categoriser pre-inputs;
determining a category by processing the categoriser input; and
automatically applying one or more animations to the set of design elements, wherein automatically applying the one or more animations to the set of design elements includes:
determining, based on the category, a first animation for the first design element; and
applying the first animation to the first design element.
